(19) United States
(12) Patent Application Publication
(10) Pub. No.: US 2026/0190572 A1
(43) Pub. Date: Jul. 2, 2026

(54) Display Device

(71) Applicant: LG Display Co., Ltd., Seoul (KR)

(72) Inventors: Jeongmin Park, Paju-si (KR); Daegyu Jo, Seoul (KR); MinJi Kang, Seocheon-gun (KR)

(21) Appl. No.: 19/202,777

(22) Filed: May 8, 2025

(30) Foreign Application Priority Data
Dec. 30, 2024 (KR) 10-2024-0200211

(51) Int. Cl. H10H 29/49; H10H 29/32; H10H 29/855

(52) U.S. Cl. CPC H10H 29/49; H10H 29/32; H10H 29/8552

(57) ABSTRACT

A display device may include a substrate including a display area, a first hole area disposed in the display area and corresponding a through hole, and a second hole area surrounding the first hole area, a pixel on the display area of the substrate, a plurality of signal lines supplying signals to the pixel and disposed so as to bypass the first hole area on the display area and the second hole area of the substrate, and a shielding pattern overlapping the second hole area.

### CROSS-REFERENCE TO RELATED APPLICATION

This application claims the priority of Republic of Korea Patent Application No. 10-2024-0200211 filed on Dec. 30, 2024, which is hereby incorporated by reference in its entirety.

### BACKGROUND

### Field

The present disclosure relates to a display device, and more particularly, to a display device including a through-hole to dispose a sensor module in a display area.

### Description of the Related Art

As it enters an information era, a display field which visually expresses electrical information signals has been rapidly developed, and in response to this, various display devices having excellent performances such as thin-thickness, light weight, and low power consumption have been developed. Examples of display devices include a liquid crystal display device (LCD) and an organic light emitting display device (OLED).

In recent years, in order to minimize a non-display area, such as a bezel of a display device, a technique for placing a sensor module including a camera device in a display area is being studied.

### SUMMARY

An object to be achieved by the present disclosure is to provide a display device which minimizes or at least reduces an influence of parasitic capacitance in the vicinity of an area in which a through-hole is disposed.

Another object to be achieved by the present disclosure is to provide a display device which improves a luminance in the vicinity of an area in which a through-hole is disposed.

Objects of the present disclosure are not limited to the above-mentioned objects, and other objects, which are not mentioned above, can be clearly understood by those skilled in the art from the following descriptions.

According to an embodiment of the present disclosure, a display device includes a substrate including a display area, a first hole area disposed in the display area and corresponding a through hole, and a second hole area surrounding the first hole area, a pixel on the display area of the substrate, a plurality of signal lines supplying signals to the pixel and disposed so as to bypass the first hole area on the display area and the second hole area of the substrate, and a shielding pattern overlapping the second hole area.

Other detailed matters of the exemplary embodiments are included in the detailed description and the drawings.

According to the exemplary embodiment of the present disclosure, a shielding pattern which overlaps a plurality of signal lines which is disposed so as to bypass a through hole in the vicinity of an area in which the through-hole is formed is used to minimize or at least reduce parasitic capacitance between the plurality of signal lines.

According to the exemplary embodiment of the present disclosure, a shielding pattern to which a constant voltage is applied is used to stably maintain a signal level of the plurality of signal lines disposed in the vicinity of the through-hole. Therefore, the luminance deviation on the display area in the vicinity of the area in which the through hole is formed may be improved.

The effects according to the present disclosure are not limited to the contents exemplified above, and more various effects are included in the present specification.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a block diagram illustrating a display device according to an exemplary embodiment of the present disclosure;

FIG. 2 is a view for explaining an example of a gate driver included in a display device of FIG. 1 according to an exemplary embodiment of the present disclosure;

FIG. 3 is a circuit diagram illustrating an example of a pixel included in a display device of FIG. 1 according to an exemplary embodiment of the present disclosure;

FIG. 4 is a plan view schematically illustrating a display device according to an exemplary embodiment of the present disclosure;

FIG. 5 is a cross-sectional view illustrating an example taken along the line IV-IV′ of FIG. 4 according to an exemplary embodiment of the present disclosure;

FIG. 6 is an enlarged plan view illustrating an example of a part EA1 of FIG. 4 according to an exemplary embodiment of the present disclosure;

FIG. 7 is an enlarged plan view illustrating an example of a part EA2 of FIG. 6 according to an exemplary embodiment of the present disclosure;

FIG. 8 is a cross-sectional view illustrating an example taken along the line I-I′ of FIG. 7 according to an exemplary embodiment of the present disclosure;

FIG. 9 is a cross-sectional view illustrating an example taken along the line II-II′ of FIG. 7 according to an exemplary embodiment of the present disclosure; and

FIG. 10 is a cross-sectional view illustrating an example of a display panel included in a display device of FIG. 4 according to an exemplary embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “comprising” used herein are generally intended to allow other components to be added unless the terms are used with the term “only”. Any references to singular may include plural unless expressly stated otherwise.

Components are interpreted to include an ordinary error range even if not expressly stated.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, the present disclosure will be described in detail with reference to accompanying drawings.

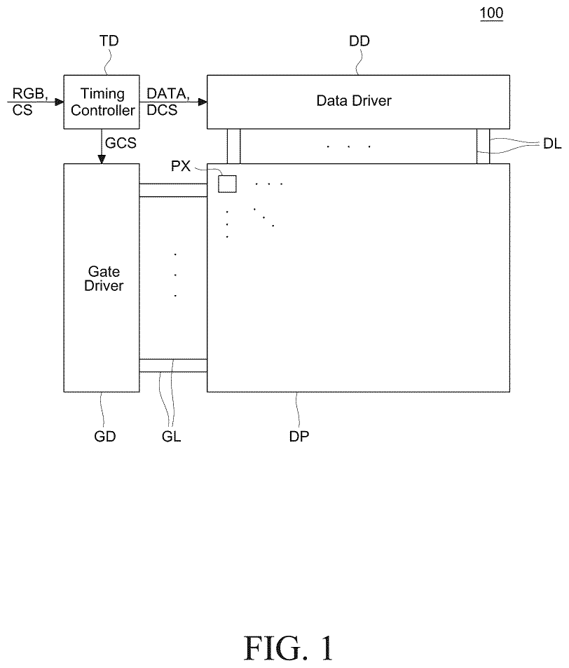

FIG. 1 is a block diagram illustrating a display device according to an exemplary embodiment of the present disclosure.

Referring to FIG. 1, a display device 100 according to an exemplary embodiment of the present disclosure may include a timing controller TD, a gate driver GD, a data driver DD, and a display panel DP.

The display panel DP may generate images to be provided to the user. For example, the display panel DP may include a display area in which a plurality of pixels PX in which a pixel circuit is disposed are disposed and a non-display area other than the display area.

Each of the plurality of pixels PX is connected to a corresponding gate line GL and a corresponding data line DL to display images in response to a gate signal supplied to the gate line GL and a data signal supplied to the data line DL.

The timing controller TD may control the gate driver GD and the data driver DD based on an input image RGB and an input control signal CS supplied from the outside, for example, a host system. For example, the input control signal CS may include timing signals, such as a horizontal synchronization signal, a vertical synchronization signal, a data enable signal, and a clock signal and the timing controller TD may generate a gate control signal GCS and a data control signal DCS based on the input control signal CS. The gate control signal GCS may be supplied to the gate driver GD and the data control signal DCS may be supplied to the data driver DD.

Further, the timing controller TD realigns an input image RGB with a digital video data format in accordance with a resolution of the display panel DP to generate image data DATA and provides the image data to the data driver DD.

The gate driver GD may generate a gate signal based on the gate control signal GCS and output the gate signal to the plurality of gate lines GL. For example, the gate driver GD may sequentially output the gate signal to the plurality of gate lines GL in the unit of pixel rows. The gate control signal GCS may include a start signal and a plurality of clock signals for generating gate signals.

In the exemplary embodiment, the gate driver GD may generate a scan signal and an emission signal based on the gate control signal GCS. For example, the gate driver GD may include at least one scan driver and at least one emission driver. The scan driver generates a scan signal in a row sequential manner to drive at least one or more scan lines connected to each pixel row to supply the scan signal to the plurality of scan lines. The emission driver generates an emission signal in a row sequential manner to drive at least one or more emission signal lines connected to each pixel row to supply the emission signal to the plurality of emission signal lines.

The data driver DD converts digital image data DATA supplied from the timing controller TD into an analog data signal based on the data control signal DCS to supply the converted analog data signal to the plurality of data lines DL.

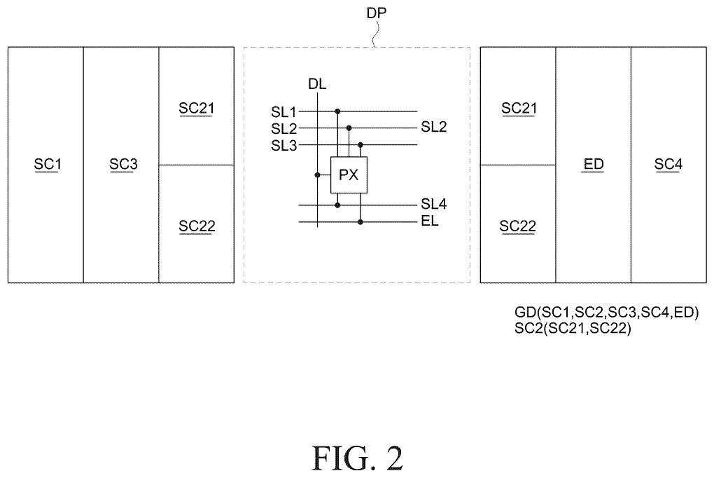

FIG. 2 is a view for explaining an example of a gate driver included in a display device of FIG. 1 according to an exemplary embodiment of the present disclosure.

Referring to FIGS. 1 and 2, the gate driver GD may supply a gate signal to the pixel PX disposed in the display panel DP. For example, the gate driver GD may include a first scan driver SC1, a second scan driver SC2, a third scan driver SC3, a fourth scan driver SC4, and an emission control driver ED. The first scan driver SC1 supplies a first scan signal through the first scan line SL1 connected to the pixel PX and the second scan driver SC2 supplies a second scan signal through the second scan line SL2 connected to the pixel PX. The third scan driver SC3 supplies a third scan signal through the third scan line SL3 connected to the pixel PX and the fourth scan driver SC4 supplies a fourth scan signal through the fourth scan line SL4 connected to the pixel PX. The emission control driver ED supplies an emission control signal through an emission control line EL connected to the pixel PX.

In the exemplary embodiment, a shift resistor included in the gate driver GD may be disposed to be symmetric on both sides of the display panel DP.

For example, shift registers included in the first scan driver SC1, the second scan driver SC2, and the third scan driver SC3 may be disposed on one side, for example, a left side of the display panel DP. For example, the second scan driver SC2 may be disposed to be the most adjacent to the display panel DP and the third scan driver SC3 may be disposed between the first scan driver SC1 and the second scan driver SC2.

Further, shift registers included in the second scan driver SC2, the fourth scan driver SC4, and the emission control driver ED may be disposed on the other side, for example, a right side of the display panel DP. For example, the second scan driver SC2 may be disposed to be the most adjacent to the display panel DP and the emission control driver ED may be disposed between the second scan driver SC2 and the fourth scan driver SC4.

According to the exemplary embodiment, the second scan drivers SC2 disposed on both sides of the display panel DP may include a first sub scan driver SC21 and a second sub scan driver SC22. Here, the first sub scan driver SC21 may include a shift register which supplies a second scan signal to pixels PX disposed in odd-numbered pixel rows, among the plurality of pixels PX disposed in the display panel DP. The second sub scan driver SC22 may include a shift register which supplies a second scan signal to pixels PX disposed in even-numbered pixel rows, among the plurality of pixels PX disposed in the display panel DP, but it is not limited thereto.

In the exemplary embodiment, as illustrated in FIG. 2, the gate driver GD may supply a gate signal from both sides of the display panel DP and/or supply a gate signal from one side of the display panel DP.

For example, the first scan driver SC1 and the third scan driver SC3 are disposed on one side, for example, a left side of the display panel DP to supply a first scan signal and a third scan signal to the plurality of pixels PX, respectively. For example, the first scan driver SC1 and the third scan driver SC3 may supply a first scan signal and a third scan signal to the plurality of pixels PX, respectively, in a single feeding manner.

Further, the fourth scan driver SC4 and the emission control driver ED are disposed on another side, for example, a right side of the display panel DP, to supply a fourth scan signal and an emission control signal to the plurality of pixels PX, respectively. Further, the fourth scan driver SC4 and the emission control driver ED may supply the fourth scan signal and the emission control signal to the plurality of pixels PX, respectively, in a single feeding manner.

The second scan drivers SC2 are disposed on both sides of the display panel DP to supply the second scan signal to the plurality of pixels PX. For example, the second scan driver SC2 may supply the second scan signal to the plurality of pixels PX in a dual feeding manner. Accordingly, the luminance deviation depending on an area of the display panel DP may be improved.

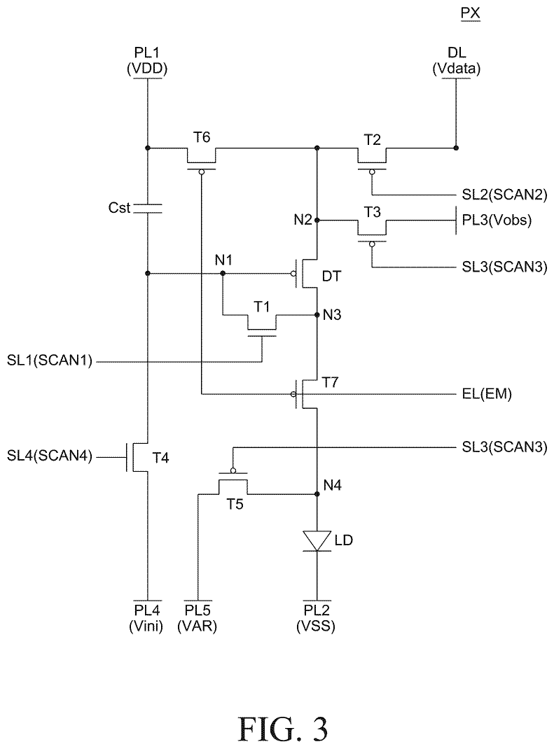

FIG. 3 is a circuit diagram illustrating an example of a pixel included in a display device of FIG. 1 according to an exemplary embodiment of the present disclosure.

In the meantime, the pixel PX illustrated in FIG. 3 represents an example of the pixel PX included in the display panel DP of the display device 100 which has been described with reference to FIG. 1.

Referring to FIG. 3, the pixel PX may include a light emitting diode LD and a pixel circuit. The pixel circuit is connected between the first power line PL1 and the second power line PL2 to control the light emitting diode LD and may include a driving transistor DT, a plurality of switching transistors T1 to T7, and a storage capacitor Cst.

In the exemplary embodiment, the driving transistor DT, a second switching transistor T2, a third switching transistor T3, a fifth switching transistor T5, a sixth switching transistor T6, and a seventh switching transistor T7 may be formed as polysilicon semiconductor transistors. For example, the driving transistor DT, the second switching transistor T2, the third switching transistor T3, the fifth switching transistor T5, the sixth switching transistor T6, and the seventh switching transistor T7 may include polysilicon semiconductor layers formed by a low temperature poly-silicon (LTPS) process as active layers (channels). Further, the driving transistor DT, the second switching transistor T2, the third switching transistor T3, the fifth switching transistor T5, the sixth switching transistor T6, and the seventh switching transistor T7 may be P-type transistors, for example, PMOS transistors. Therefore, a gate-on voltage which turns on the driving transistor DT, the second switching transistor T2, the third switching transistor T3, the fifth switching transistor T5, the sixth switching transistor T6, and the seventh switching transistor T7 may be a logic low level.

The polysilicon semiconductor transistor has an advantage of fast response speed so that it may be applied to a switching element which requires fast switching.

Further, in one exemplary embodiment, the first switching transistor T1 and the fourth switching transistor T4 may be formed as oxide semiconductor transistors. For example, the first switching transistor T1 and the fourth switching transistor T4 may be N-type oxide semiconductor transistors, for example, NMOS transistors and include an oxide semiconductor layer as an active layer. Therefore, a gate-on voltage which turns on the first switching transistor T1 and the fourth switching transistor T4 may be a logic high level.

The oxide semiconductor transistor is processed at a low temperature and has a lower charge mobility than the polysilicon semiconductor transistor. That is, the oxide semiconductor transistor has an excellent off-current characteristic. Accordingly, when the first switching transistor T1 and the fourth switching transistor T4 are formed as oxide semiconductor transistors, the leakage current from the third node N3 according to the low frequency driving may be minimized and thus a display quality may be improved.

However, the driving transistor DT and the plurality of switching transistors T1 to T7 are not limited thereto. Therefore, at least one of the driving transistor DT, the second switching transistor T2, the third switching transistor T3, the fifth switching transistor T5, the sixth switching transistor T6, and the seventh switching transistor T7 may be formed as the oxide semiconductor transistor. Further, at least one of the first switching transistor T1 and the fourth switching transistor T4 may be formed as a polysilicon semiconductor transistor.

The driving transistor DT is connected between the first power line PL1 which supplies a first power voltage VDD, for example, a high potential power voltage and a second power line PL2 which supplies a second power voltage VSS, for example, a low potential power voltage. The driving transistor DT may include a gate electrode connected to the first node N1. For example, the first electrode, for example, a source electrode of the driving transistor DT may be connected to the second node N2 and the second electrode, for example, a drain electrode may be connected to the third node N3.

The driving transistor DT may control a driving current, for example, a current amount of a driving current which flows to the second power line PL2 from the first power line PL1 via the light emitting diode LD in response to the voltage of the first node N1 corresponding to the gate electrode. To this end, the first power voltage VDD may be set to be greater than the second power voltage VSS. For example, the first power voltage VDD may be a positive voltage and the second power voltage VSS may be a negative voltage.

According to the exemplary embodiment, the first power line PL1 and the second power line PL2 may be formed as a line on the display panel DP, but are not limited thereto.

The first switching transistor T1 may be connected between the gate electrode and the second electrode of the driving transistor DT, for example, between the first node N1 and the third node N3 and may be connected to the first scan line SL1. For example, the first electrode, for example, a source electrode of the first switching transistor T1 may be connected to the first node N1 and the second electrode, for example, a drain electrode may be connected to the third node N3. When a turn-on level of first scan signal SCAN1 is supplied to the first scan line SL1, the first switching transistor T1 is turned on to electrically connect the gate electrode and the second electrode of the driving transistor DT. In this case, the driving transistor DT may be connected in a diode form.

The second switching transistor T2 may be connected between the data line DL and the second node N2 and may be connected to the second scan line SL2. For example, the first electrode, for example, a source electrode of the second switching transistor T2 may be connected to the data line DL and the second electrode, for example, a drain electrode may be connected to the second node N2. When a turn-on level of second scan signal SCAN2 is supplied to the second scan line SL2, the second switching transistor T2 is turned on to electrically connect the data line DL and the second node N2. In this case, the data signal Vdata which is supplied to the data line DL may be supplied to the second node N2.

The third switching transistor T3 may be connected between the second node N2, for example, the first electrode of the driving transistor DT and the third power line PL3 which supplies a bias voltage Vobs and includes a gate electrode connected to the third scan line SL3. For example, the first electrode, for example, a source electrode of the third switching transistor T3 may be connected to the third power line PL3 and the second electrode, for example, a drain electrode may be connected to the second node N2. When a turn-on level of third scan signal SCAN3 is supplied to the third scan line SL3, the third switching transistor T3 is turned on to supply the bias voltage Vobs to the second node N2.

In the exemplary embodiment, the bias voltage Vobs may have a level which is similar to a voltage level of a black gray scale of data signal Vdata. For example, the bias voltage Vobs may have a voltage level of approximately 5 V to 7 V, but is not limited thereto.

Accordingly, the third switching transistor T3 is turned on to apply a predetermined high voltage to the first electrode of the driving transistor DT. Here, if the first switching transistor T1 is in a turned-off state, the driving transistor DT may be in an on-bias state (that is, to be on-biased). Here, as the bias voltage Vobs is periodically supplied to the second node N2, the bias state of the driving transistor DT may be periodically changed and a threshold voltage characteristic of the driving transistor DT may be changed. Accordingly, the characteristic of the driving transistor DT may be suppressed from being fixed to a specific state in the low-frequency driving to be degraded.

The fourth switching transistor T4 may be connected between the first node N1 and the fourth power line PL4 which supplies an initialization voltage Vini and includes a gate electrode connected to the fourth scan line SL4. For example, the first electrode, for example, a source electrode of the fourth switching transistor T4 may be connected to the first node N1 corresponding to the gate electrode of the driving transistor DT and the second electrode, for example, a drain electrode may be connected to the fourth power line PL4. When a turn-on level of fourth scan signal SCAN4 is supplied to the fourth scan line SL4, the fourth switching transistor T4 is turned on to supply the initialization voltage Vini to the first node N1, that is, the gate electrode of the driving transistor DT. In this case, the gate electrode of the driving transistor DT may be initialized by the initialization voltage Vini. To this end, the initialization voltage Vini may be set to a voltage which is lower than a lowest level of the data signal Vdata.

The fifth switching transistor T5 may be connected between the first electrode of the light emitting diode LD, for example, the fourth node N4 and the fifth power line PL5 which supplies the reset voltage VAR and includes a gate electrode connected to the third scan line SL3. For example, the first electrode, for example, a source electrode of the fifth switching transistor T5 may be connected to the fifth power line PL5 and the second electrode, for example, a drain electrode may be connected to the fourth node N4. When a turn-on level of the third scan signal SCAN3 is supplied to the third scan line SL3, the fifth switching transistor T5 is turned on to supply a reset voltage VAR to the fourth node N4, for example, the first electrode of the light emitting diode LD. In this case, the parasitic capacitor of the light emitting diode LD may be discharged by the reset voltage VAR. A remaining voltage charged in a parasitic capacitor is discharged (removed) so that unintended minute light emission may be suppressed. Accordingly, a black expression ability of the pixel PX may be improved.

The sixth switching transistor T6 may be connected between the first power line PL1 and the second node N2, for example, the first electrode of the driving transistor DT and include a gate electrode connected to the emission control line EL. For example, the first electrode, for example, a source electrode of the sixth switching transistor T6 may be connected to the first power line PL1 and the second electrode, for example, a drain electrode may be connected to the second node N2. The sixth switching transistor T6 may be turned on or turned off by the emission control signal EM which is supplied to the emission control line EL. When the sixth switching transistor T6 is turned on, the second node N2 may be electrically connected to the first power line PL1.

The seventh switching transistor T7 may be connected between the third node N3 and the fourth node N4, for example, the second electrode of the driving transistor DT and the first electrode of the light emitting diode LD and include a gate electrode connected to the emission control line EL. For example, the first electrode, for example, a source electrode of the seventh switching transistor T7 may be connected to the third node N3 and the second electrode, for example, a drain electrode may be connected to the fourth node N4. The seventh switching transistor T7 may be controlled in the substantially same manner as the sixth switching transistor T6. When the seventh switching transistor T7 is turned on, the third node N3 and the fourth node N4 may be electrically connected.

In the meantime, in accordance with the above-described operation of the sixth switching transistor T6 and the seventh switching transistor T7, if a turn-on level of emission control signal EM is supplied to turn on both the sixth switching transistor T6 and the seventh switching transistor T7, a current path in which a current flows from the first power line PL1 to the light emitting diode LD via the driving transistor DT may be formed. Accordingly, the light emitting diode LD may emit light in response to the driving current.

In the meantime, even though it is illustrated in FIG. 2 that the sixth switching transistor T6 and the seventh switching transistor T7 are connected to the same emission control line EL, this is illustrative and the exemplary embodiment of the present disclosure is not limited thereto. For example, the sixth switching transistor T6 and the seventh switching transistor T7 may be connected to separate emission control lines to which different emission control signals are supplied.

The storage capacitor Cst may be connected between the first power line PL1 and the first node N1. As one electrode of the storage capacitor Cst is connected to the first power line PL1 to which a first power voltage VDD which is a constant voltage is supplied, the voltage of the first node N1 is not affected by the parasitic capacitance and may maintain a voltage level of a voltage which is directly supplied to the first node N1. That is, the storage capacitor Cst may store a voltage applied to the first node N1.

The first electrode of the light emitting diode LD, for example, the anode electrode may be connected to the fourth node N4 and the second electrode, for example, the cathode electrode may be connected to the second power line PL2. The light emitting diode LD may generate light with a predetermined luminance in response to a driving current supplied from the driving transistor DT.

In the meantime, in FIG. 2, it is illustrated that a pixel PX has a pixel circuit structure which includes eight transistors and one capacitor, but this is just illustrative. Therefore, the pixel PX may have a pixel circuit structure in which an additional transistor and/or capacitor is included and/or at least any one of the transistor and the capacitor illustrated in FIG. 2 is omitted.

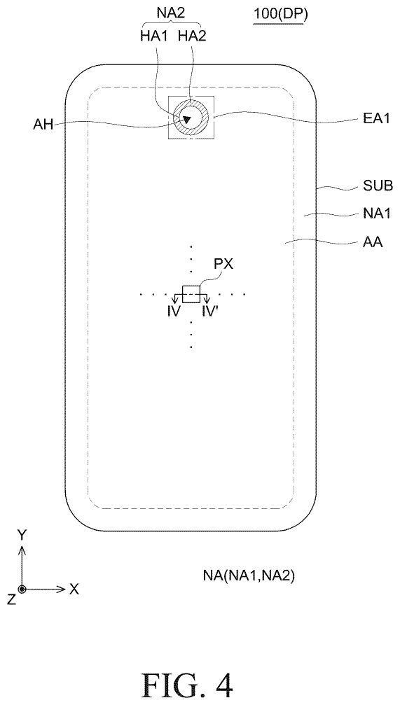

FIG. 4 is a plan view schematically illustrating a display device according to an exemplary embodiment of the present disclosure.

Referring to FIG. 4, the display device 100 according to the exemplary embodiment of the present disclosure may include a display panel DP and the display panel DP may include a display area AA and a non-display area NA.

The display area AA may be defined as an area where images are displayed. For example, the display panel DP may include a substrate SUB and a plurality of pixels PX disposed on the display area AA of the substrate SUB.

One pixel PX may include a plurality of sub pixels which emit different color of light. For example, one pixel PX uses three sub pixels to implement blue light, red light, and green light. However, it is not limited thereto, and in some cases, the pixel PX may further include a sub pixel for further implementing a specific color, for example, white light.

In the pixel PX, an area which implements blue may be referred to as a blue sub pixel, an area which implements red may be referred to as a red sub pixel, and an area which implements green may be referred to as a green sub pixel.

The display device 100 may display an image through a display area AA. A display surface defined by the display area AA may be parallel to a surface defined by a first directional axis, for example, an axis extending in the first direction X and a second directional axis, for example, an axis extending in the second direction Y. A normal direction of the display surface, that is, a thickness direction of the display device 100 may be defined as a third direction Z.

Front surfaces (or top surfaces) and rear surfaces (or bottom surfaces) of components or units of the display device 100 to be described below may be distinguished along the third direction Z. However, the first direction X, the second direction Y, and the third direction Z illustrated in the present disclosure are just illustrative and the direction X, the second direction Y, and the third direction Z are relative concepts to be changed to other directions. Hereinafter, for the convenience of description, the same reference numeral is denoted to the direction X, the second direction Y, and the third direction Z.

In the meantime, when it is represented as “overlapping”, it means that two components overlap in the thickness direction, for example, the third direction Z of the display device 100, unless otherwise defined.

In the meantime, in FIG. 1, even though it is illustrated that the display panel DP included in the display device 100 has a rounded corner at which one long side and one short side intersect, this is just illustrative and the shape of the display panel DP is not limited thereto. For example, the display panel DP may have an angled shape at the corner in which one long side and one short side intersect.

In one exemplary embodiment, the display panel DP may include a flat display area AA, but is not limited thereto. For example, the display panel DP may include a curved display area or a three-dimensional display area.

In the meantime, the display area AA may be used not only as an area in which images are displayed, but also as an area in which a touch input of a user is recognized, for example, a sensing area or a touch area. In this case, the display device 100 may further include a touch sensor.

The non-display area NA may be defined as an area where no image is displayed. The non-display area NA may include a first non-display area NA1 disposed so as to surround an outside of the display area AA and a second non-display area NA2 disposed in the display area AA.

The first non-display area NA1 may be located at the outside of the display area AA. However, this is illustrative and it is not limited thereto so that a shape of the display area AA and a shape of the first non-display area NA1 may be relatively designed.

In one exemplary embodiment, the second non-display area NA2 may be formed to be surrounded by the display area AA. That is, the second non-display area NA2 may be located inside the display area AA. The second non-display area NA2 may be defined as an area which includes a through hole AH and does not display images.

In the exemplary embodiment, the second non-display area NA2 may include a first hole area HA1 corresponding to the through hole AH and a second hole area HA2 which is disposed so as to surround the first hole area HA1.

In the exemplary embodiment, a shielding pattern which overlaps at least a part of the second hole area HA2 may be disposed. For example, the shielding pattern includes a metal material and may be patterned so as to correspond to the second hole area HA2. For example, the shielding pattern may overlap the second hole area HA2 and may not overlap the first hole area HA1. For example, the shielding pattern may have a circular shape or an oval ring shape so as to correspond to the shape of the second hole area HA2, but is not limited thereto.

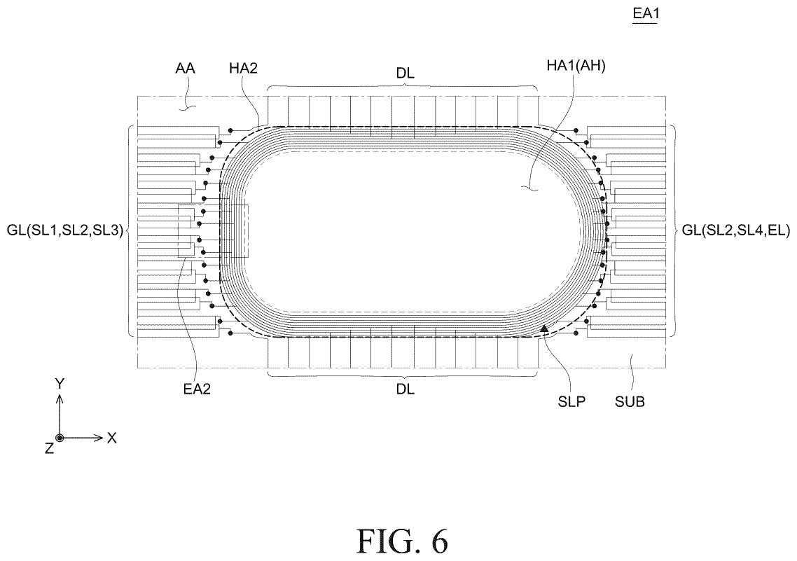

The shielding pattern will be described in more detail with reference to FIGS. 6 to 10.

The through hole AH may have a circular shape or an oval shape on the plane. However, the shape of the through hole AH may be modified in various forms without being limited thereto. For example, the through hole AH may have a polygonal shape including a square shape on the plane or an irregular shape.

The through hole AH may pass through at least a part of the display panel DP. Accordingly, an area of the display panel DP in which the though hole AH is formed in the second non-display area NA2 may be defined as a first hole area HA1 and an area excluding the first hole area HA1 may be defined as a second hole area HA2.

In the second hole area HA2, a pixel PX is not disposed, but various wiring lines which transmit a signal or a driving voltage to the pixel PX, for example, a data line DL, a plurality of scan lines SL1 to SL4, the emission control line EL and/or the plurality of power lines PL1 to PL5 may be disposed. For example, the wiring lines may be disposed on the second hole area HA2 so as to bypass the first hole area HA1 with respect to the through hole AH.

At least one sensor module may be disposed below the display device 100, for example, on a rear surface which is opposite to a front surface of the display panel DP so as to correspond to the through hole AH. For example, at least one sensor module may be disposed so as to overlap the through hole AH. For example, the sensor module may include at least one of an image sensor (or a camera), an illumination sensor, a proximity sensor, an infrared sensor, and an ultrasound sensor.

As described above, the display device 100 may include a through hole AH formed in the second non-display area NA2 and include a sensor module which is disposed so as to overlap the through hole AH. Accordingly, the display device may have a dead space which is minimized as compared with another display device in which the sensor module is disposed only on one side of the display area AA, for example, in the first non-display area NA1.

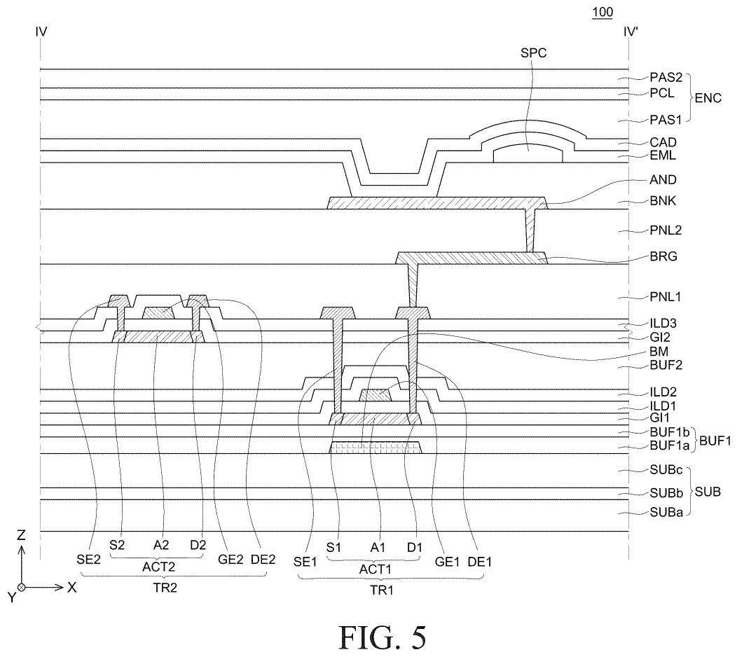

FIG. 5 is a cross-sectional view illustrating an example taken along the line IV-IV′ of FIG. 4 according to one embodiment.

For example, in FIG. 5, a cross-sectional view illustrating an example of a pixel PX included in the display device 100 is illustrated. For example, each of the first transistor TR1 and the second transistor TR2 illustrated in FIG. 5 may be any one of the driving transistor DT and the plurality of switching transistors T1 to T7 included in the pixel PX which has been described with reference to FIG. 3.

According to the exemplary embodiment, the first transistor TR1 of FIG. 5 may be any one of transistors which are polysilicon semiconductor transistors, among the transistors included in the pixel PX. For example, the first transistor TR1 may be any one of the driving transistor DT, the second switching transistor T2, the third switching transistor T3, the fifth switching transistor T5, the sixth switching transistor T6, and the seventh switching transistor T7 included in the pixel PX.

Further, the second transistor TR2 of FIG. 5 may be any one of transistors which are oxide semiconductor transistors, among the transistors included in the pixel PX. For example, the second transistor TR2 may be any one of the first switching transistor T1 and the fourth switching transistor T4 included in the pixel PX.

Further, in FIG. 5, a light emitting diode which is connected to the pixel PX is illustrated together.

Referring to FIG. 5, a first transistor TR1, a second transistor TR2, and a light emitting diode LD may be disposed on the substrate SUB.

The substrate SUB is a base member of the display panel DP and may be substantially a transparent and transmissive substrate. The substrate SUB may be a flexible substrate formed of a plastic material. For example, the substrate SUB may include polyimide (PI).

In the meantime, when the substrate SUB includes polyimide (PI), moisture passes through the substrate SUB formed of polyimide (PI) and permeates the thin film transistor included in the pixel PX so that the reliability of the pixel PX may be lowered and thus a performance of the display device 100 may be degraded.

Accordingly, in one exemplary embodiment, the substrate SUB may include double polyimides (PI). Further, the substrate SUB further includes an inorganic film formed between two polyimides (PI) to block the moisture components from permeating the lower polyimide (PI), so that the reliability of the product performance may be further improved. Further, an inorganic film is formed between two polyimides (PI) to block charges charged in polyimide (PI) disposed in a lower portion, thereby improving the reliability of the product.

For example, as illustrated in FIG. 5, the substrate SUB may include a first sub substrate SUBa including polyimide (PI), a second substrate SUBb which is disposed on the first sub substrate SUBa and includes an inorganic insulating material, and a third sub substrate SUBc which is disposed on the second sub substrate SUBb and includes polyimide PI.

A light shielding layer BM may be disposed on the substrate SUB. The light shielding layer BM may be disposed below a transistor, for example, a semiconductor layer of the first transistor TR1 and includes a metal material. As described above, the light shielding layer BM including a metal material is disposed below the first transistor TR1 which is a polysilicon semiconductor transistor, to suppress threshold voltage shift of the transistor, thereby improving the reliability.

To this end, the light shielding layer BM may be disposed so as to overlap at least a part of a semiconductor layer of the first transistor TR1, for example, a semiconductor pattern ACT1.

The first buffer layer BUF1 may be disposed on the substrate SUB. For example, the first buffer layer BUF1 may be disposed on the substrate SUB so as to cover the light shielding layer BM.

The first buffer layer BUF1 may serve to improve an adhesive strength between configurations formed thereabove and the substrate SUB and block moisture or oxygen permeating through the substrate SUB.

For example, the first buffer layer BUF1 may include a multi-buffer layer BUF1a disposed on the substrate SUB and an active buffer layer BUF1b disposed on the multi-buffer layer BUF1a, but is not limited thereto.

The first transistor TR1 may be disposed on the first buffer layer BUF1. For example, a semiconductor pattern ACT1, a gate electrode GE1, a source electrode SE1, and a drain electrode DE1 of the first transistor TR1 may be disposed on the first buffer layer BUF1.

The first semiconductor layer may be disposed on the first buffer layer BUF1. For example, the first semiconductor layer is a semiconductor layer including polysilicon and may form semiconductor patterns of the driving transistor DT, the second switching transistor T2, the third switching transistor T3, the fifth switching transistor T5, the sixth switching transistor T6, and the seventh switching transistor T7 which have been described with reference to FIG. 3.

For example, the semiconductor pattern ACT1 of the first transistor TR1 may be disposed on the first buffer layer BUF1. The semiconductor pattern ACT1 of the first transistor TR1 may include a first region S1, a second region D1, and a channel region A1 between the first region S1 and the second region D1. For example, the first region S1 and the second region D1 may be a source region and a drain region of the semiconductor pattern ACT1, respectively.

The first gate insulating layer GI1 may be disposed on the first buffer layer BUF1. For example, the first gate insulating layer GI1 may be disposed on the first buffer layer BUF1 so as to cover the first semiconductor layer, for example, the semiconductor pattern ACT1 of the first transistor TR1 to insulate the semiconductor pattern ACT1 of the first transistor TR1 from the gate electrode G1.

The gate electrode GE1 of the first transistor TR1 may be disposed on the first gate insulating layer GI1. The gate electrode GE1 of the first transistor TR1 may be disposed so as to overlap at least a part of the semiconductor pattern ACT1.

A first insulating layer ILD1 may be disposed on the first gate insulating layer GI1. For example, the first insulating layer IDL1 may be disposed on the first gate insulating layer GI1 so as to cover the gate electrode GE1 of the first transistor TR1.

A second insulating layer ILD2 may be disposed on the first insulating layer ILD1. Even though it is not illustrated in FIG. 5, in the exemplary embodiment, a shielding pattern which has been described with reference to FIG. 4 may be disposed between the first insulating layer ILD1 and the second insulating layer ILD2, this will be described below with reference to FIGS. 6 to 10.

A second buffer layer BUF2 may be disposed on the second insulating layer ILD2. The second buffer layer BUF2 may planarize an upper portion and cover components disposed therebelow.

The second transistor TR2 may be disposed on the second buffer layer BUF2. For example, a semiconductor pattern ACT2, a gate electrode GE2, a source electrode SE2, and a drain electrode DE2 of the second transistor TR2 may be disposed on the second buffer layer BUF2.

The second semiconductor layer may be disposed on the second buffer layer BUF2. For example, the second semiconductor layer is a semiconductor layer including oxide semiconductor and may form semiconductor patterns of the first switching transistor T1 and the fourth switching transistor T4 which have been described with reference to FIG. 3.

For example, the semiconductor pattern ACT2 of the second transistor TR2 may be disposed on the second buffer layer BUF2. The semiconductor pattern ACT2 of the second transistor TR2 may include a first region S2, a second region D2, and a channel region A2 therebetween. For example, the first region S2 and the second region D2 may be a source region and a drain region of the semiconductor pattern ACT2, respectively.

The second gate insulating layer GI2 may be disposed on the second buffer layer BUF2. For example, the second gate insulating layer GI2 is disposed on the second buffer layer BUF2 so as to cover the second semiconductor layer, for example, the semiconductor pattern ACT2 of the second transistor TR2 to insulate the semiconductor pattern ACT2 of the second transistor TR2 from the gate electrode GE2.

The gate electrode GE2 of the second transistor TR1 may be disposed on the second gate insulating layer GI2. The gate electrode GE2 of the second transistor TR2 may be disposed so as to overlap at least a part of the semiconductor pattern ACT2.

A third insulating layer ILD3 may be disposed on the second gate insulating layer GI2. For example, the third insulating layer IDL3 may be disposed on the second gate insulating layer GI2 so as to cover the gate electrode GE2 of the second transistor TR2.

A source electrode SE1 and a drain electrode DE1 of the first transistor TR1 may be disposed on the third insulating layer ILD3. The source electrode SE1 and the drain electrode DE1 of the first transistor TR1 may be in contact with the first region S1 and the second region D1 of the semiconductor pattern ACT1 through at least one contact hole. The at least one contact hole passes through the third insulating layer ILD3, the second gate insulating layer GI2, the second buffer layer BUF2, the second insulating layer ILD2, the first insulating layer ILD1, and the first gate insulating layer GI1.

Further, a source electrode SE2 and a drain electrode DE2 of the second transistor TR2 may be disposed on the third insulating layer ILD3. The source electrode SE2 and the drain electrode DE2 of the second transistor TR2 may be in contact with the first region S2 and the second region D2 of the semiconductor pattern ACT2 through at least one contact hole which passes through the third insulating layer ILD3 and the second gate insulating layer GI2.

A first planarization layer PNL1 may be disposed on the third insulating layer ILD3. For example, the first planarization layer PNL1 may be disposed on the third insulating layer ILD3 so as to cover the source electrodes SE1 and SE2 and the drain electrodes DE1 and DE2 of the first transistor TR1 and the second transistor TR2 to planarize an upper portion and protect components disposed therebelow.

A bridge electrode BRG may be disposed on the first planarization layer PNL1. The bridge electrode BRG may be in contact with the first transistor TR1, for example, the drain electrode DE1 of the first transistor TR1, through at least one contact hole which passes through the first planarization layer PNL1.

A second planarization layer PNL2 may be disposed on the first planarization layer PNL1. For example, the second planarization layer PNL2 may be disposed so as to cover the bridge electrode BRG on the first planarization layer PNL1.

The second planarization layer PNL2 may be an organic layer which planarizes an upper portion and protects components disposed therebelow.

The light emitting diode LD may be disposed on the second planarization layer PNL2. The light emitting diode LD may include a first electrode and a second electrode, for example, an anode electrode AND and a cathode electrode CAD and include an emission layer EML formed therebetween.

The anode electrode AND may be disposed on the second planarization layer PNL2. The anode electrode AND may be connected to the bridge electrode BRG through a through hole which passes through the second planarization layer PNL2 to expose at least a part of the bridge electrode BRG. Accordingly, the anode electrode AND may be connected to the drain electrode DE1 of the first transistor TR1 through the bridge electrode BRG.

A bank layer BNK may be disposed so as to cover at least a part of the anode electrode AND and open the remaining part of the anode electrode AND. For example, the bank layer BNK may be disposed to open a part corresponding to an emission area of the pixel PX. Therefore, a part of the anode electrode AND may be exposed by the open part of the bank layer BNK. In the meantime, a spacer SPC may be further disposed on the bank layer BNK.

The emission layer EML may be disposed on the entire surface of the pixel PX on top surfaces of the bank layer BNK and the anode electrode AND. For example, the emission layer EML may be disposed on an area of the above-described display area AA excluding the second non-display area NA2. In the meantime, a part of the emission layer EML may be in contact with the exposed part of the anode electrode AND by the open part of the bank layer BNK.

The cathode electrode CAD may be disposed on the emission layer EML. For example, at least a part of the second power line PL2 which supplies a second power voltage VSS to the pixel PX may configure the cathode electrode CAD of the light emitting diode LD.

The light emitting diode LD may be formed by the anode electrode AND, the emission layer EML, and the cathode electrode CAD.

An encapsulation layer ENC which protects the light emitting diode LD of the pixel PX from moisture permeation from the outside may be disposed on the light emitting diode LD.

The encapsulation layer ENC may have a single-layer structure or a multi-layered structure. For example, the encapsulation layer ENC may include a first encapsulation layer PAS1, a second encapsulation layer PAS2, and a third encapsulation layer PCL between the first encapsulation layer PAS1 and the second encapsulation layer PAS2.

The encapsulation layer ENC may include a transparent material to allow light emitted from the light emitting diode LD to pass through. For example, the first encapsulation layer PAS1 and the second encapsulation layer PAS2 may include inorganic materials having transparency and the third encapsulation layer PCL may be disposed between the first encapsulation layer PAS1 and the second encapsulation layer PAS2 and include organic materials having transparency.

FIG. 6 is an enlarged plan view illustrating an example of a part EA1 of FIG. 4 according to one embodiment.

For example, FIG. 6 illustrates a second non-display area NA2 including a first hole area HA1 in which a through hole AH on the display panel DP which has been described with reference to FIG. 4 is formed and a second hole area HA2 disposed so as to surround the first hole area HA1 and a part of the display area AA. The display area AA is adjacent to the second non-display area NA2.

Referring to FIGS. 4 to 6, the second non-display area NA2 may be disposed in the display area AA.

The first hole area HA1 of the second non-display area NA2 is an area corresponding to the through hole AH formed in the display panel DP and the pixel PX and wiring lines for supplying various signals and driving voltages to the pixel PX may not be disposed therein.

Further, the second hole area HA2 may be disposed so as to surround the first hole area HA1. Accordingly, the second hole area HA2 may have a circular shape or an oval ring shape so as to correspond to the shape of the through hole AH, for example, the first hole area HA1, but is not limited thereto.

Various wiring lines for supplying a signal or a driving voltage to the plurality of pixels PX disposed in the display area AA may be disposed on the second hole area HA2 so as to bypass the first hole area HA1 with respect to the through hole AH.

To be more specific, a gate line GL which is supplied with a signal from the gate driver GD disposed on one side of the display area AA along the first direction X may be disposed on the second hole area HA2 so as to extend to the first direction X in the display area AA corresponding to one side of the second non-display area NA2 along the first direction X and bypass the first hole area HA1. Further, the gate line GL may be disposed so as to extend to the first direction X in the display area AA corresponding to the other side of the second non-display area NA2 along the first direction X.

For example, as described above, the first scan driver SC1, the second scan driver SC2, and the third scan driver SC3 may be disposed on one side of the display area AA along the first direction X, for example, on the left side to supply a first scan signal SCAN1, a second scan signal SCAN2, and a third scan signal SCAN3 to the pixel PX. Therefore, each of the first scan line SL1, the second scan line SL2, and the third scan line SL3 may be disposed to extend to the first direction X in the display area AA corresponding to one side of the second non-display area NA2 along the first direction X, for example, the left side and then bypass the first hole area HA1 on the second hole area HA2. Further, each of the first scan line SL1, the second scan line SL2, and the third scan line SL3 may be disposed to extend to the first direction X in the display area AA corresponding to the other side of the second non-display area NA2 along the first direction X, for example, the right side.

Further, a gate line GL which is supplied with a signal from the gate driver GD disposed on the other side of the display area AA along the first direction X may be disposed so as to extend to the first direction X in the display area AA corresponding to the other side of the second non-display area NA2 along the first direction X and bypass the first hole area HA1 on the second hole area HA2. Further, the gate line GL may be disposed so as to extend to the first direction X in the display area AA corresponding to one side of the second non-display area NA2 along the first direction X.

For example, as described above, the second scan driver SC2, the fourth scan driver SC4, and the emission control driver ED are disposed on the other side of the display area AA along the first direction X, for example, on the right side to supply a second scan signal SCAN2, a fourth scan signal SCAN4, and an emission control signal EM to the pixel PX. Therefore, each of the second scan line SL2, the fourth scan line SL4, and the emission control line EL may be disposed to extend to the first direction X in the display area AA corresponding to the other side of the second non-display area NA2 along the first direction X, for example, the right side and then bypass the first hole area HA1 on the second hole area HA2. Further, each of the second scan line SL2, the fourth scan line SL4, and the emission control line EL may be disposed to extend to the first direction X in the display area AA corresponding to one side of the second non-display area NA2 along the first direction X, for example, the left side.

Further, the data line DL which supplies a data signal Vdata from the data driver DD may be disposed so as to extend to the second direction Y in the display area corresponding to one side of the second non-display area NA2 along the second direction Y and bypass the first hole area HA1 on the second hole area HA2. Further, the data line may be disposed so as to extend to the second direction Y in the display area AA corresponding to the other side of the second non-display area NA2 along the second direction Y.

According to the exemplary embodiment, at least some of wiring lines for transmitting signals to the pixel PX, for example, the data line DL, the plurality of scan lines SL1 to SL4, and the emission control line EL may be disposed on the same layer. In this case, the wiring lines may be disposed so as to be spaced apart from each other so that the wiring lines disposed on the same layer are not connected, for example, are not shorted. That is, the wiring lines disposed on the same layer may be disposed so as not to overlap each other.

Further, according to the exemplary embodiment, at least some of wiring lines for transmitting signals to the pixel PX, for example, the data line DL, the plurality of scan lines SL1 to SL4, and the emission control line EL may be disposed on different layers.

In the meantime, in the present disclosure, among the wiring lines for transmitting signals to the pixel PX, for example, the data line DL, the plurality of scan lines SL1 to SL4, and the emission control line EL, a part which is disposed on the second hole area HA2 so as to bypass the first hole area HA1 may be referred to as a link line.

In the exemplary embodiment, a shielding pattern SLP which overlaps at least a part of the second hole area HA2 may be disposed. For example, the shielding pattern SLP may be formed to overlap all the wiring lines disposed in the second hole area HA2, for example, the data line DL, the plurality of scan lines SL1 to SL4, and the emission control line EL.

According to the exemplary embodiment, the shielding pattern SLP may be patterned so as to correspond to the shape of the second hole area HA2. In this case, the shielding pattern SLP may overlap the second hole area HA2 and may not overlap the first hole area HA1. For example, the shielding pattern SLP may have a circular shape or an oval ring shape so as to correspond to the shape of the second hole area HA2.

In one exemplary embodiment, the shielding pattern SLP includes a metal material and a constant voltage may be applied to the shielding pattern SLP. For example, the shielding pattern SLP may be electrically connected to any one power line of the above-described power lines PL1 to PL5. For example, the shielding pattern SLP may be electrically connected to a second power line PL2 which supplies a low potential power voltage, for example, a second power voltage VSS.

Further, the shielding pattern SLP may be disposed between the above-described signal lines, for example, the data line DL, the plurality of scan lines SL1 to SL4, and the emission control line EL. For example, at least some of the data line DL, the plurality of scan lines SL1 to SL4, and the emission control line EL may be disposed above the shielding pattern SLP, for example, on at least one insulating layer which is disposed on the shielding pattern SLP. The remaining may be disposed below the shielding pattern SLP, for example, on at least one insulating layer which is disposed below the shielding pattern SLP.

In this case, a parasitic capacitance between the above-described signal lines, for example, the data line DL, the plurality of scan lines SL1 to SL4, and the emission control line EL may be suppressed and each signal line may form a capacitance with the shielding pattern SLP. Here, a second power voltage VSS which is a constant voltage is applied to the shielding pattern SLP so that signal levels of signals supplied to the signal lines, for example, the data signal Vdata, the plurality of scan signals SCAN1 to SCAN4, and the emission control signal EM supplied to the data line DL, the plurality of scan lines SL1 to SL4, and the emission control line EL may be stably maintained. Accordingly, even though the overlay of the signal lines is distorted due to the process dispersion in the vicinity of the second non-display area NA2, for example, an area in which the through hole AH is formed, the signal level of the signal lines is stably maintained to improve the luminance on the display area AA.

In the meantime, the exemplary embodiment of the present disclosure is not limited thereto and any one voltage of a first power voltage VDD, a second power voltage VSS, a bias voltage Vobs, an initialization voltage Vini, and a reset voltage VAR, among constant voltages, may be applied to the shielding pattern SLP.

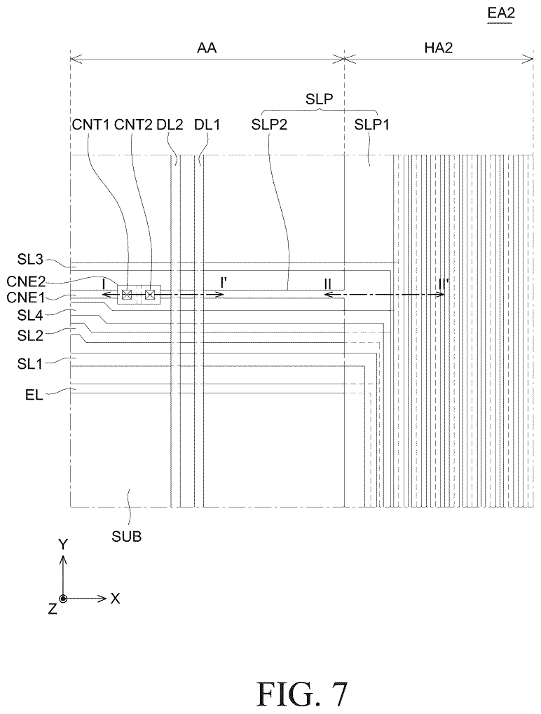

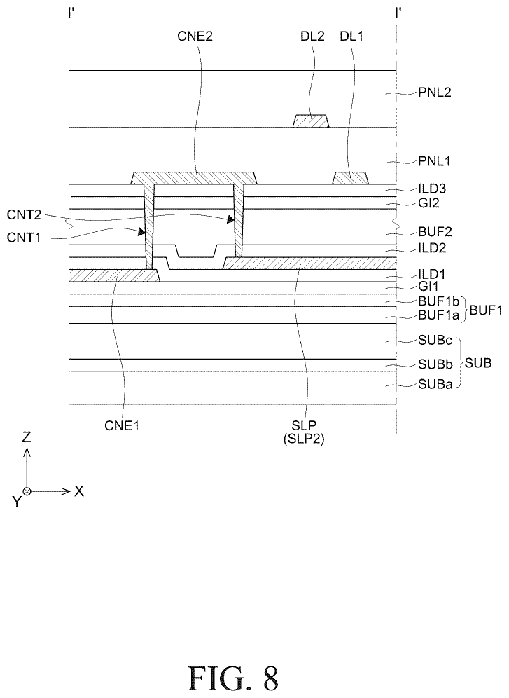

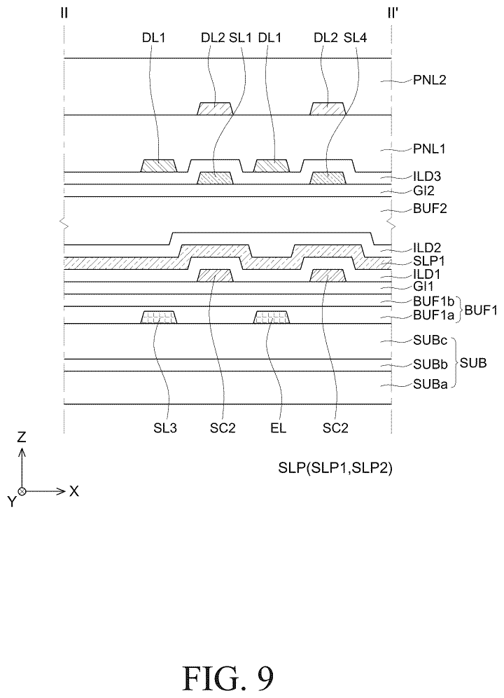

FIG. 7 is an enlarged plan view illustrating an example of a part EA2 of FIG. 6 according to one embodiment. FIG. 8 is a cross-sectional view illustrating an example taken along the line I-I′ of FIG. 7 according to one embodiment. FIG. 9 is a cross-sectional view illustrating an example taken along the line II-II′ of FIG. 7 according to one embodiment.

For example, in FIG. 7, a part of a display area AA located on one side of at least a part of the second non-display area NA2, for example, one side of the second hole area HA2 and the second non-display area NA2 along the first direction X, for example, a left side is illustrated.

In the meantime, for the convenience of description, in the cross-sectional views of FIGS. 8 and 9, a redundant description for the contents which have been described with reference to FIG. 5 is not repeated.

First, referring to FIGS. 4 to 7, the first scan line SL1, the second scan line SL2, the third scan line SL3, the fourth scan line SL4, and the emission control line EL may extend to the first direction X in the display area AA and the data line DL may extend in the second direction Y in the display area AA.

Further, as described above, the first scan line SL1, the second scan line SL2, the third scan line SL3, the fourth scan line SL4, the emission control line EL, and the data line DL may be disposed so as to bypass the first hole area HA1 in the second non-display area NA2, for example, in the second hole area HA2.

In the meantime, as described above, the first scan driver SC1, the second scan driver SC2, and the third scan driver SC3 may be disposed on the left side of the display area AA and the second scan driver SC2, the fourth scan driver SC4, and the emission control driver ED may be disposed on the right side of the display area AA. Accordingly, the first scan line SL1 and the third scan line SL3 illustrated in FIG. 7 are connected to the first scan driver SC1 and the third scan driver SC3 located on the left side of the display area AA to be supplied with signals. The fourth scan line SL4 and the emission control line EL are connected to the fourth scan driver SC4, and the emission control driver ED located on the right side of the display area AA to be supplied with signals. The second scan line SL2 is connected to the second scan driver SC2 disposed on both sides of the display area AA to be supplied with signals.

In the meantime, among the data lines DL illustrated in FIG. 7, the first data line DL1 and the second data line DL2 may be disposed on different layers and supply the data signal Vdata to the pixels PX located on different pixel rows. For example, the first data line DL1 may supply a data signal Vdata to pixels PX disposed in odd-numbered pixel rows and the second data line DL2 may supply a data signal Vdata to pixels PX disposed in even-numbered pixel rows. As described above, when the data lines corresponding to adjacent pixel rows are located on different layers, even though the interval between the adjacent data lines DL, that is, the first data line DL1 and the second data line DL2, for example, an interval along the first direction X is designed to be minimized, the short between the data lines DL may be suppressed. Accordingly, a high resolution display panel DP may be designed.

The shielding pattern SLP1 may include a first shielding pattern SLP1 disposed in the second hole area HA2 and a second shielding pattern SLP2 disposed in the display area AA.

For example, the first shielding pattern SLP1 may be disposed so as to overlap the second hole area HA2 and have a shape corresponding to a shape of the second hole area HA2. For example, the first shielding pattern SLP1 is a planar pattern and may have a circular shape or an oval ring shape so as to correspond to the shape of the second hole area HA2.

Further, as described with reference to FIG. 6, the first shielding pattern SLP1 may be disposed so as to overlap all various signal lines disposed in the second hole area HA2.

The second shielding pattern SLP2 may be disposed to be connected to the first shielding pattern SLP1 and extend in the first direction X. For example, the second shielding pattern SLP2 has a line shape which is branched from the first shielding pattern SLP1 to extend in the first direction X and may be disposed on the display area AA.

According to the exemplary embodiment, the first shielding pattern SLP1 and the second shielding pattern SLP2 may be simultaneously formed by the same process. For example, the first shielding pattern SLP1 and the second shielding pattern SLP2 may be integrally formed.

In the exemplary embodiment, the second shielding pattern SLP2 may be connected to the first connection electrode CNE1 and the second connection electrode CNE2. For example, one end of the first connection electrode CNE1 may be connected to one end of the second connection electrode CNE2 through a first contact hole CNT1 and the other end of the second connection electrode CNE2 may be connected to the second shielding pattern SLP2 through a second contact hole CNT2.

Here, a constant voltage may be applied to the first connection electrode CNE1. For example, the first connection electrode CNE1 may be connected to a power line which supplies a constant voltage, for example, the second power line PL2 which supplies a second power voltage VSS. Accordingly, the second power voltage VSS supplied from the second power line PL2 may be applied to the shielding pattern SLP through the first connection electrode CNE1 and the second connection electrode CNE2.

A connection structure of the first connection electrode CNE1, the second connection electrode CNE2, and the shielding pattern SLP will be described in more detail with reference to FIG. 8. The first connection electrode CNE1, the second connection electrode CNE2, and the shielding pattern SLP may be disposed on different layers and may be electrically connected to each other through the contact holes CNT1 and CNT2.

To be more specific, the first connection electrode CNE1 may be disposed on the first gate insulating layer GI1. For example, the first connection electrode CNE1 may be disposed between the first gate insulating layer GI1 and the first insulating layer ILD1.

In one exemplary embodiment, the first connection electrode CNE1 may be disposed on the same layer as a gate electrode of at least one transistor included in the pixel PX. For example, the first connection electrode CNE1 is included in the pixel PX and may be disposed on the same layer as the polysilicon semiconductor transistor, for example, the gate electrode GE1 of the first transistor TR1. For example, the first connection electrode CNE1 may include the same material as the gate electrode GE1 of the first transistor TR1, and may be simultaneously formed by the same process.

The second connection electrode CNE2 may be disposed on the third insulating layer ILD3. For example, the second connection electrode CNE2 may be disposed between the third insulating layer ILD3 and the first planarization layer PNL1.

In one exemplary embodiment, the second connection electrode CNE2 may be disposed on the same layer as a source electrode and a drain electrode of at least one transistor included in the pixel PX. For example, the second connection electrode CNE2 may be disposed on the same layer as the source electrodes SE1 and SE2 and the drain electrodes DE1 and DE2 of the first transistor TR1 and the second transistor TR2 included in the pixel PX. For example, the second connection electrode CNE2 may include the same material as the source electrodes SE1 and SE2 and the drain electrodes DE1 and DE2 of the first transistor TR1 and the second transistor TR2 and may be simultaneously formed by the same process.

One end of the second connection electrode CNE2 may be connected to one end of the first connection electrode CNE1. For example, at least a part of the second connection electrode CNE2 may be disposed so as to overlap the first connection electrode CNE1 and may be in contact with the first connection electrode CNE1 through the first contact hole CNT1. The first contact hole CNT1 passes through the third insulating layer ILD3, the second gate insulating layer GI2, the second buffer layer BUF2, the second insulating layer ILD2, and the first insulating layer ILD1.

The shielding pattern SLP, for example, the second shielding pattern SLP2 may be disposed on the first insulating layer ILD1. For example, the second shielding pattern SLP2 may be disposed between the first insulating layer ILD1 and the second insulating layer ILD2.

Further, the other end of the second connection electrode CNE2 may be connected to the second shielding pattern SLP2. For example, at least a part of the second connection electrode CNE2 may be disposed so as to overlap the second shielding pattern SLP2 and may be in contact with the second shielding pattern SLP2 through the second contact hole CNT2. The second contact hole CNT2 passes through the third insulating layer ILD3, the second gate insulating layer GI2, the second buffer layer BUF2, and the second insulating layer ILD2.

As described above, the second connection electrode CNE2 may be disposed so as to overlap at least a part of each of the first connection electrode CNE1 and the second shielding pattern SLP2 so as to be connected to each of the first connection electrode CNE1 and the second shielding pattern SLP2 through different contact holes CNT1 and CNT2. However, the first connection electrode CNE1 and the second shielding pattern SLP2 may be disposed so as not to overlap each other.

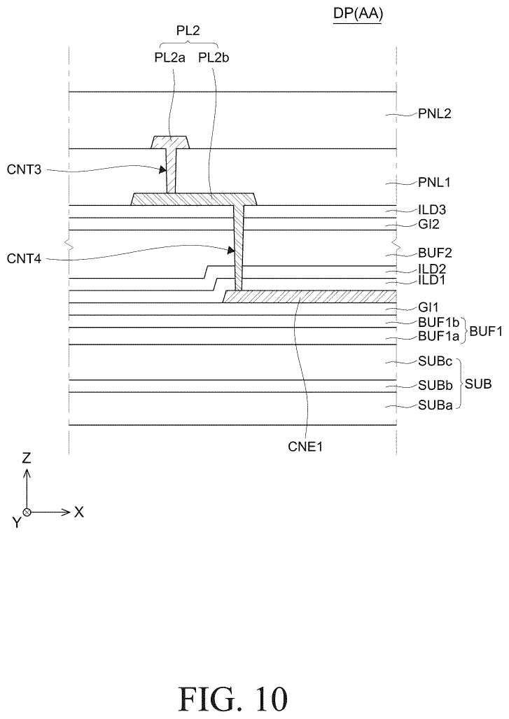

Further, the first connection electrode CNE1 may be connected to a power line which supplies a constant voltage, for example, the second power line PL2 which supplies a second power voltage VSS to be supplied with the second power voltage VSS. Accordingly, the second power voltage VSS may be supplied to the shielding pattern SLP through the first connection electrode CNE1 and the second connection electrode CNE2. A detailed description thereof will be made below with reference to FIG. 10.

Next, a placement relationship of various signal lines disposed on the second hole area HA2, for example, the first data line DL1, the second data line DL2, the plurality of scan lines SL1 to SL4, and the emission control line EL will be described with reference to FIG. 9. The first data line DL1, the second data line DL2, the first scan line SL1, the second scan line SL2, the third scan line SL3, the fourth scan line SL4, and the emission control line EL may be disposed on a layer different from that of the shielding pattern SLP. At least some of the lines may be disposed above the shielding pattern SLP and the remaining may be disposed below the shielding pattern SLP.

To be more specific, the first data line DL1, the second data line DL2, the first scan line SL1, and the fourth scan line SL4 may be disposed above the shielding pattern SLP.

The first data line DL1 may be disposed on the third insulating layer ILD3. For example, the first data line DL1 may be disposed between the third insulating layer ILD3 and the first planarization layer PNL1.

In one exemplary embodiment, the first data line DL1 may be disposed on the same layer as a source electrode and a drain electrode of at least one transistor included in the pixel PX. For example, the first data line DL1 may be disposed on the same layer as the source electrodes SE1 and SE2 and the drain electrodes DE1 and DE2 of the first transistor TR1 and the second transistor TR2 included in the pixel PX. For example, the first data line DL1 may include the same material as the source electrodes SE1 and SE2 and the drain electrodes DE1 and DE2 of the first transistor TR1 and the second transistor TR2 and may be simultaneously formed by the same process.

In this case, the first data line DL1 may be disposed on the same layer as the above-described second connection electrode CNE2. For example, the first data line DL1 may include the same material as the second connection electrode CNE2 and may be simultaneously formed by the same process.

The second data line DL2 may be disposed on the first planarization layer PNL1. For example, the second data line DL2 may be disposed between the first planarization layer PNL1 and the second planarization layer PNL2.

As described above, the first data line DL1 and the second data line DL2 may be disposed on different layers and may be disposed so as not to overlap each other.

In one exemplary embodiment, the second data line DL2 may be disposed on the same layer as the bridge electrode BRG included in the pixel PX. For example, the second data line DL2 may include the same material as the bridge electrode BRG and may be simultaneously formed by the same process.

The first scan line SL1 may be disposed on the second gate insulating layer GI2. For example, the first scan line SL1 may be disposed between the second gate insulating layer GI2 and the third insulating layer ILD3.

In one exemplary embodiment, the first scan line SL1 may be disposed on the same layer as a gate electrode of at least one transistor included in the pixel PX. For example, the first scan line SL1 may be included in the pixel PX and may be disposed on the same layer as the oxide semiconductor transistor, for example, the gate electrode GE2 of the second transistor TR2. For example, the first scan line SL1 may include the same material as the gate electrode GE2 of the second transistor TR2, and may be simultaneously formed by the same process.

The fourth scan line SL4 may be disposed on the second gate insulating layer GI2. For example, the fourth scan line SL4 may be disposed between the second gate insulating layer GI2 and the third insulating layer ILD3.

In one exemplary embodiment, the fourth scan line SL4 may be disposed on the same layer as a gate electrode of at least one transistor included in the pixel PX. For example, the fourth scan line SL4 may be included in the pixel PX and may be disposed on the same layer as the oxide semiconductor transistor, for example, the gate electrode GE2 of the second transistor TR2. For example, the fourth scan line SL4 may include the same material as the gate electrode GE2 of the second transistor TR2, and may be simultaneously formed by the same process.

In this case, the first scan line SL1 and the fourth scan line SL4 may be disposed on the same layer to be spaced apart from each other. For example, the first scan line SL1 and the fourth scan line SL4 may include the same material and may be simultaneously formed by the same process and may be formed to be spaced apart from each other.

According to the exemplary embodiment, the first scan line SL1 and the fourth scan line SL4 may be disposed so as to overlap the second data line DL2. For example, each of the first scan line SL1 and the fourth scan line SL4 may be disposed so as to overlap the second data line DL2 as seen from the plan view.

Further, the second scan line SL2, the third scan line SL3, and the emission control line EL may be disposed below the shielding pattern SLP.

The second scan line SL2 may be disposed on the first gate insulating layer GI1. For example, the second scan line SL2 may be disposed between the first gate insulating layer GI1 and the first insulating layer ILD1.

In one exemplary embodiment, the second scan line SL2 may be disposed on the same layer as a gate electrode of at least one transistor included in the pixel PX. For example, the second scan line SL2 may be included in the pixel PX and may be disposed on the same layer as the polysilicon semiconductor transistor, for example, the gate electrode GE1 of the first transistor TR1. For example, the second scan line SL2 may include the same material as the gate electrode GE1 of the first transistor TR1, and may be simultaneously formed by the same process.

In this case, the second scan line SL2 may be disposed on the same layer as the above-described first connection electrode CNE1. For example, the second scan line SL2 may include the same material as the first connection electrode CNE1 and may be simultaneously formed by the same process.

The third scan line SL3 may be disposed on the substrate SUB. For example, the third scan line SL3 may be disposed between the substrate SUB and the first buffer layer BUF1.

In one exemplary embodiment, the third scan line SL3 may be disposed on the same layer as the light shielding layer BM. For example, the third scan line SL3 may include the same material as the light shielding layer BM and may be simultaneously formed by the same process.

The emission control line EL may be disposed on the substrate SUB. For example, the emission control line EL may be disposed between the substrate SUB and the first buffer layer BUF1.

In one exemplary embodiment, the emission control line EL may be disposed on the same layer as the light shielding layer BM. For example, the emission control line EL may include the same material as the light shielding layer BM and may be simultaneously formed by the same process.

In this case, the third scan line SL3 and the emission control line EL may be disposed on the same layer to be spaced apart from each other. For example, the third scan line SL3 and the emission control line EL may include the same material and may be simultaneously formed by the same process and may be formed to be spaced apart from each other.

In the meantime, as described above, the shielding pattern SLP, for example, the second shielding pattern SLP2 which is disposed in the second hole area HA2 in which the signal lines bypass the first hole area HA1 in which the through holes AH are disposed may be disposed on the entire second hole area HA2 to overlap all the signal lines.

Here, the shielding pattern SLP is applied with the second power voltage VSS which is a constant voltage. Therefore, the first data line DL1, the second data line DL2, the first scan line SL1, and the fourth scan line SL4 disposed above the shielding pattern SLP may not form a parasitic capacitance with the second scan line SL2, the third scan line SL3, and the emission control line EL disposed below the shielding pattern SLP, but may form the capacitance with the shielding pattern SLP. Likewise, the second scan line SL2, the third scan line SL3, and the emission control line EL which are disposed below the shielding pattern SLP may also form a capacitance with the shielding pattern SLP.

In this case, a second power voltage VSS which is a constant voltage is applied to the shielding pattern SLP. Therefore, signal levels of signals supplied to the signal lines, for example, the data signal Vdata, the plurality of scan signals SCAN1 to SCAN4, and the emission control signal EM supplied to the data line DL, the plurality of scan lines SL1 to SL4, and the emission control line EL may be stably maintained by the parasitic capacitance formed by the shielding pattern SLP.

Accordingly, the signal level of the signal lines disposed in the vicinity of the area in which the through hole AH is formed is stably maintained to improve the luminance on the display area AA in the vicinity of the area in which the through hole AH is formed.

FIG. 10 is a cross-sectional view illustrating an example of a display panel included in a display device of FIG. 4 according to one embodiment.

Referring to FIG. 10, the second power line PL2 which supplies a second power voltage VSS to a pixel PX may be disposed on the display area AA of the display panel DP. For example, the second power line PL2 may be disposed on the display area AA in a line shape (for example, a line shape of a mesh structure), but is not limited thereto.

The second power line PL2 may include a first sub power line PL2a and a second sub power line PL2b. The first sub power line PL2a may be disposed between the third insulating layer ILD3 and the first planarization layer PNL1 and the second sub power line PL2b may be disposed between the first planarization layer PNL1 and the second planarization layer PNL2. The second sub power line PL2b may be in contact with the first sub power line PL2a through a third contact hole CNT3 which passes through the first planarization layer PNL1.

Further, in one exemplary embodiment, the first sub power line PL2a may overlap at least a part of the first connection electrode CNE1 and may be in contact with the first connection electrode CNE1 through a fourth contact hole CNT4. The fourth contact hole CNT4 passes through the third insulating layer ILD3, the second gate insulating layer GI2, the second buffer layer BUF2, the second insulating layer ILD2, and the first insulating layer ILD1.

Therefore, the second power voltage VSS which is a constant voltage supplied through the second power line PL2, for example, the first sub power line PL2a and the second sub power line PL2b may be supplied to the first connection line CNE1.

As described above, according to the exemplary embodiment of the present disclosure, a shielding pattern which overlaps the plurality of signal lines disposed to bypass the through hole in the vicinity of the area in which the through hole is formed may be provided.

For example, some of the plurality of signal lines may be disposed above the shielding pattern and the remaining signal lines may be disposed below the shielding pattern.

Here, the shielding pattern may include a metal material and the constant voltage may be applied to the shielding pattern. Accordingly, the parasitic capacitance is not formed between the plurality of signal lines, but the capacitance may be formed between the plurality of signal lines and the shielding pattern.

Accordingly, the signal level of the plurality of signal lines disposed in the vicinity of the area in which the through hole is formed may be stably maintained to improve the luminance on the display area in the vicinity of the area in which the through hole is formed.

The exemplary embodiments of the present disclosure can also be described as follows:

According to an embodiment of the present disclosure, a display device includes a substrate including a display area, a first hole area disposed in the display area and corresponding a through hole, and a second hole area surrounding the first hole area, a pixel on the display area of the substrate, a plurality of signal lines supplying signals to the pixel and disposed so as to bypass the first hole area on the display area and the second hole area of the substrate, and a shielding pattern overlapping the second hole area.

A constant voltage may be applied to the shielding pattern.

The shielding pattern may include a metal material.

The shielding pattern may overlap all the plurality of signal lines disposed in the second hole area.

At least some of the plurality of signal lines in the second hole area may be disposed above the shielding pattern and the remaining signal lines may be disposed below the shielding pattern.

The shielding pattern may be patterned so as to correspond to a shape of the second hole area.

The shielding pattern may have a circular or oval ring shape.

The shielding pattern may not overlap the first hole area.

The plurality of signal lines may include a first scan line, a second scan line, a third scan line, a fourth scan line, and an emission control line extending in a first direction in the display area, and a first data line and a second data line extending in a second direction which is different from the first direction in the display area.

The shielding pattern may include a first shielding pattern overlapping the second hole area and a second shielding pattern connected to the first shielding pattern and extended in the first direction.

The second shielding pattern may be connected to at least one connection electrode extending in the first direction through at least one contact hole, and a constant voltage may be applied to the at least one connection electrode.

The third scan line and the emission control line may be disposed on the same layer, the second scan line may be disposed on the third scan line and the emission control line, the first scan line and the fourth scan line may be disposed on the same layer and disposed on the second scan line, the first data line may be disposed on the first scan line and the fourth scan line, and the second data line may be disposed on the first data line.

The shielding pattern may be disposed between the second scan line and the first scan line or between the second scan line and the fourth scan line.

The display device may further include a light shielding layer disposed below at least one transistor included in the pixel, the third scan line may be disposed on the same layer as the light shielding layer and may include the same material as the light shielding layer.

The display device may further include a light shielding layer disposed below at least one transistor included in the pixel, the emission control line may be disposed on the same layer as the light shielding layer and may include the same material as the light shielding layer.

The display device may further include a first connection electrode disposed on the same layer as the second scan line.

The display device may further include a second connection electrode disposed on the same layer as the first data line.

The second connection electrode may be in contact with the first connection electrode through a first contact hole which passes through at least one insulating layer disposed between the first connection electrode and the second connection electrode, and the second connection electrode may be in contact with the shielding pattern through a second contact hole which passes through at least one insulating layer disposed between the shielding pattern and the second connection electrode.

The pixel may include a pixel circuit connected between a first power line which supplies a first power voltage and a second power line which supplies a second power voltage and a light emitting diode connected to the pixel circuit and the first connection electrode may be connected to the second power line.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device comprising:
a substrate including a display area, a first hole area in the display area and corresponding to a through hole, and a second hole area surrounding the first hole area;
a pixel on the display area of the substrate;
a plurality of signal lines supplying signals to the pixel, the plurality of signal lines bypassing the first hole area on the display area and the second hole area of the substrate; and
a shielding pattern overlapping the second hole area.

2. The display device according to claim 1, wherein a constant voltage is applied to the shielding pattern.

3. The display device according to claim 1, wherein the shielding pattern includes a metal material.

4. The display device according to claim 1, wherein the shielding pattern overlaps all of the plurality of signal lines in the second hole area.

5. The display device according to claim 4, wherein at least some of the plurality of signal lines in the second hole area are above the shielding pattern and remaining signal lines are below the shielding pattern.

6. The display device according to claim 1, wherein the shielding pattern is patterned so as to correspond to a shape of the second hole area.

7. The display device according to claim 6, wherein the shielding pattern has a circular or oval ring shape.

8. The display device according to claim 1, wherein the shielding pattern is non-overlapping with the first hole area.

9. The display device according to claim 1, wherein the plurality of signal lines include a first scan line, a second scan line, a third scan line, a fourth scan line, and an emission control line extending in a first direction in the display area, and a first data line and a second data line extending in a second direction that is different from the first direction in the display area.

10. The display device according to claim 9, wherein the shielding pattern includes:
a first shielding pattern overlapping the second hole area; and
a second shielding pattern connected to the first shielding pattern and extending in the first direction.

11. The display device according to claim 10, wherein the second shielding pattern is connected to at least one connection electrode extending in the first direction through at least one contact hole, and
wherein a constant voltage is applied to the at least one connection electrode.

12. The display device according to claim 9, wherein the third scan line and the emission control line are on a same layer,
wherein the second scan line is on the third scan line and the emission control line,
wherein the first scan line and the fourth scan line are on a same layer and on the second scan line,
wherein the first data line is on the first scan line and the fourth scan line, and
wherein the second data line is on the first data line.

13. The display device according to claim 12, wherein the shielding pattern is between the second scan line and the first scan line or between the second scan line and the fourth scan line.

14. The display device according to claim 12, further comprising:
a light shielding layer below at least one transistor included in the pixel,
wherein the third scan line is on a same layer as the light shielding layer and includes a same material as the light shielding layer.

15. The display device according to claim 12, further comprising:
a light shielding layer below at least one transistor included in the pixel,
wherein the emission control line is on a same layer as the light shielding layer and includes a same material as the light shielding layer.

16. The display device according to claim 13, further comprising:
a first connection electrode on a same layer as the second scan line.

17. The display device according to claim 16, further comprising:
a second connection electrode on a same layer as the first data line.

18. The display device according to claim 17, wherein the second connection electrode is in contact with the first connection electrode through a first contact hole which passes through at least one insulating layer that is between the first connection electrode and the second connection electrode, and
wherein the second connection electrode is in contact with the shielding pattern through a second contact hole which passes through at least one insulating layer that is between the shielding pattern and the second connection electrode.

19. The display device according to claim 18, wherein the pixel includes a pixel circuit connected between a first power line which supplies a first power voltage and a second power line which supplies a second power voltage and a light emitting diode connected to the pixel circuit, and
wherein the first connection electrode is connected to the second power line.
